(19) United States
(12) Patent Application Publication
(10) Pub. No.: US 2021/0288207 A1
(43) Pub. Date: Sep. 16, 2021

(54) HIGH TEMPERATURE ACID ETCH FOR SILICON

(71) Applicant: 1366 TECHNOLOGIES INC., Bedford, MA (US)

(72) Inventors: Ralf JONCZYK, Concord, MA (US); Patrick MCMAHON, Framingham, MA (US)

(21) Appl. No.: 17/202,023

(22) Filed: Mar. 15, 2021

Related U.S. Application Data
(60) Provisional application No. 62/990,025, filed on Mar. 16, 2020.

(51) Int. Cl. H01L 31/18

(52) U.S. Cl. CPC H01L 31/182

(57) ABSTRACT

A method includes etching silicon using a mixture of nitric acid and hydrofluoric acid in which less than 6 mols of hydrofluoric acid is used to etch one mol of silicon. The etching may be conducted at an elevated temperature, such as a temperature of at least 70 degrees Celsius.

### FIELD

The embodiments of the present disclosure relate generally to semiconductor device manufacturing and specifically to a method of etching silicon using a mixture of acids.

### BACKGROUND

Solar cell processing typically requires a substantial amount of etching, such as etching of the silicon wafer of the solar cell. This can be done using an alkaline etch, an acid etch or a dry plasma etch. The objective is typically removal of some undesired surface feature (sawing damage, release of coating residue, etc.) and/or to texture at least one surface of the wafer to improve light trapping. Monocrystalline (i.e., single crystalline) silicon wafers are typically textured using an alkaline etch. This etch is relatively expensive but results in very good texture and removal of the sawing damage in one etch step. Multi-crystalline (i.e., polycrystalline) silicon (e.g., polysilicon) wafers typically undergo an acid etch that provides some texture, such as an ISO etch or a metal assisted etch.

Reactive ion etching (RIE) is sometimes used to improve the wafer texture to the same quality as seen with alkaline etching in monocrystalline wafers. Both the acid etch and the RIE etch are costly due to the high equipment cost and consumption of expensive chemicals, such as hydrofluoric acid (HF). Hydrofluoric acid consumption is high because the acid etch reaction requires 6 mols of HF for each mol of silicon etched. Also, for the etch to be effective and fast, a relatively high concentration of chemicals in general, and HF specifically, has to be maintained. This leads to large amounts of acid lost due to displacement of the existing etch bath whenever new chemicals are added.

### SUMMARY

According to one embodiment, a method comprises etching silicon using a mixture of nitric acid and hydrofluoric acid in which less than 6 mols of hydrofluoric acid is used to etch one mol of silicon at an elevated temperature.

According to another embodiment, a method comprises etching silicon using a mixture of nitric acid and hydrofluoric acid at a temperature of at least 70 degrees Celsius.

According to another embodiment, a method comprises etching silicon using a mixture of nitric acid, hydrofluoric acid and sulfuric acid at above room temperature.

### DESCRIPTION OF THE EMBODIMENTS

According to one embodiment, silicon is etched using a mixture of nitric acid and hydrofluoric acid in which less than 6 mols of hydrofluoric acid is used to etch one mol of silicon at an elevated temperature. Preferably, about 4 mols (e.g., 3.8 to 4.2 mols) of hydrofluoric acid are used to etch one mol of silicon, as will be described in more detail below. Furthermore 2 moles or less, such as 1 to 2 moles, of the nitric acid are used to etch one mol of the silicon.

In one embodiment, the etching is conducted at a temperature above room temperature. As used herein above room temperature means above 25 degrees Celsius. For example, the etching is conducted at a temperature of at least 70 degrees Celsius, such as a temperature of 70 to 130 degrees Celsius. Preferably, the etching is conducted at a temperature of at least 90 degrees Celsius, such as a temperature of 90 to 110 degrees Celsius.

As will be described in more detail below, during the etching, the nitric acid oxidizes the silicon to silicon dioxide, and the hydrofluoric acid dissolves the silicon dioxide. For example, the nitric acid oxidizes the silicon to the silicon dioxide by forming nitrogen dioxide which oxidizes the silicon according to equation (I):

Si+2HNO₃→SiO₂+2NO₂+H₂O (I).

The hydrofluoric acid dissolves the silicon oxide according to equation (II):

SiO₂+4HF→SiF₄+2H₂O (II).

In one embodiment, the reaction products of the etching comprise silicon tetrafluoride gas and water vapor according to equation (II) above. Preferably, the reaction products of the etching consist essentially of the silicon tetrafluoride gas and the water vapor, and include less than 1 mol percent of H₂SiF₆ based on the total amount of the reaction products, such as 0 to 0.5 mol percent H₂SiF₆.

In one embodiment, the mixture further comprises a metal catalyst (e.g., a copper or silver compound, such as silver nitrate) which is used to catalyze the oxidation reaction described above and to texture the silicon by metal catalyzed chemical etching. In this embodiment, the reaction stoichiometry follows closely that which is described in equations (I) and (II) above. Therefore the etch composition including a metal catalyst allows for simultaneous low cost etching and the creation of adequate texture for light capture.

In one embodiment, the mixture further comprises a diluent comprising, but not limited to, sulfuric acid in addition to the nitric and hydrofluoric acids. In one embodiment, the diluent consists essentially of the sulfuric acid. In another embodiment, the diluent includes sulfuric acid and water. The etching is started when the mixture contacts the silicon in a vessel. For example, the mixture is placed into the vessel (such as an etching tank) to create an etching bath. The silicon (e.g., silicon wafer, etc.) is then placed into the etching bath in the vessel.

Preferably, the diluent includes primarily sulfuric acid (e.g., at least 50 volume percent sulfuric acid, such as 50 to 100 volume percent, such as 65 to 80 volume percent, including 70 to 75 volume percent sulfuric acid) with up to 50 volume percent water (e.g., 0 to 50 volume percent, such as 20 to 35 volume percent, including 25 to 30 volume percent water). Without wishing to be bound by a particular theory, the sulfuric acid may also participate in the silicon etch in addition to being a diluent by increasing the etching rate of silicon, possibly by oxidizing the silicon to silicon dioxide.

The acids may be added to the initial mixture (i.e., the etching bath) as aqueous solutions. Water may be added to the initial mixture as a diluent and/or as part of the acid aqueous solutions. In one embodiment, the initial mixture (i.e., the etching bath) contains, by volume, 30 to 80 percent, such as 60 to 70 percent sulfuric acid, 0 to 50 percent such as 25 to 40 percent water, 0.01 to 10 percent, such as 2 to 5 percent nitric acid, and 0.01 to 10 percent, such as 0.1 to 1 percent hydrofluoric acid. The initial mixture may also optionally include a trace amount (e.g., less than 0.5 volume percent, such as 0.001 to 0.1 volume percent) metal catalyst (e.g., a copper or silver compound, such as silver nitrate). In one embodiment, the initial mixture may exclude any other compound or element other than unavoidable impurities. In another embodiment, the initial mixture may include other optional compounds or elements.

Thus, the initial mixture (i.e., etching bath) which contacts the silicon to begin the etching may include nitric acid, hydrofluoric acid, sulfuric acid and water. After the mixture contacts the silicon (e.g., when the silicon is placed in a vessel containing the mixture, i.e., in the fresh etching bath), various additional reaction products, such as water vapor and silicon tetrafluoride gas, are generated. Preferably, only the nitric and hydrofluoric acid are the active etching ingredients in the mixture, and the sulfuric acid acts generally as an inactive diluent, but could under some circumstances, also etch silicon. In one embodiment, there is no liquid bleed from the vessel during the etching. After the etching is completed (e.g., after the silicon, such as the silicon wafer is removed from the etching bath in the vessel), the liquid etching bath may be removed from the vessel.

Any suitable silicon may be etched using the above mixture. Preferably, the silicon comprises polycrystalline silicon. However, monocrystalline silicon or amorphous silicon may also be etched using the mixture. In one embodiment, the silicon comprises a polycrystalline silicon wafer. The wafer may be used as a solar cell wafer, such that a solar cell (such as a silicon p-n or p-i-n junction solar cell) is formed on the polycrystalline silicon wafer after the etching. In alternative embodiments, the silicon may comprise a monocrystalline silicon wafer, or a silicon layer located above a wafer in a semiconductor device. For example, the silicon layer may be a polysilicon layer located in a solar cell or in another semiconductor device above a substrate.

The acidic silicon etch can be considerably more efficient when operating at a higher temperature (i.e., above room temperature), such as 70 to 130 degrees Celsius, and with sulfuric acid as a diluent, rather than water. Sulfuric acid is relatively inexpensive and allows etching at high temperatures due to its high boiling point of greater than 300 degrees Celsius. At the higher temperatures (e.g., at 70 degrees Celsius and above) several advantages occur during the etching process.

First, the nitric acid, regardless of stoichiometric ratios, needs to be converted to nitrogen dioxide (NO₂) to effectively oxidize the silicon. Nitrogen dioxide is generated from nitric acid more rapidly at the higher temperatures (e.g., at 70 degrees Celsius and above) than at room temperature. Therefore, less nitric acid may be used to etch silicon at the higher temperatures due to the more rapid generation of nitrogen dioxide.

The second advantage is that the reaction changes from producing a liquid reaction product of hexafluorosilicic acid (H₂SiF₆), which builds up and cannot be removed from the etching bath in the etching vessel without removing the active etching chemicals, to producing silicon tetrafluoride (SiF₄) gas. This reduces the amount of HF required to etch one mol of silicon from 6 mols HF per mol of silicon to 4 mols HF per mol of silicon. SiF₄ is a gas and therefore the main reaction product (Si) can be constantly removed from the bath very easily, without removing active etching chemicals.

The third advantage is that there is no need to bleed (i.e., remove) liquid etching chemicals consumed (i.e., the reaction products) during the etching reaction from the etching bath to make room for fresh make-up etching chemicals (e.g., fresh nitric and hydrofluoric acid). In a conventional etching process, the bleed material includes both the reaction products and unused etching chemicals from the bath. Bleeding chemistry from an active mixture effectively removes a fraction of the reaction products to create a steady state composition, but simultaneously removes unused active chemicals. A given minimum makeup of the active chemicals is required to replace that which was unused in the liquid phase bleed material in order to maintain steady state etching conditions and chemistry. A separate given minimum makeup of the active chemicals is required to replace that which is used in the reaction. This results in additional waste of the unused etching chemicals.

In contrast, by avoiding bleeding liquid phase material from the bath, the waste of the unused etching chemicals is avoided. This is due to a) the low amount of fresh etching chemicals required compared to the conventional etching process, b) the higher temperature that results in evaporation of water (which is a byproduct of the reaction, i.e., a reaction product), and c) the production of a gaseous product (SiF₄) which can continuously evolve out of solution. These three effects result in the amount of makeup etching chemicals added to the bath being the same as the loss of liquid due to evaporation and liquid drag-out (i.e., liquid left on the silicon wafers after being etched) when transferring the silicon wafers from the etching bath to a rinse station.

Furthermore, because sulfuric acid has a low vapor pressure and the main reactants (HF, HNO₃) are nearly completely consumed during the reaction, what evaporates from the bath is mostly water and SiF₄ (The boiling point of SiF₄ is −86 degrees Celsius.). This evaporation is advantageous because water and SiF₄ are the reaction products and would cause the etching reaction to stall eventually if they are not removed from the etching bath. The evaporation of the vapor phase reaction products from the etching bath avoids the necessity to bleed liquid phase material from the bath. The net effect is a reduction in HF consumption by about 50%, reduction in nitric acid consumption by as much as 80% and a reduction in waste acid by up to 90%.

Another advantage of the embodiment etching process is that a mild texture is generated in the etched silicon. The mild texture may comprise shallow pitting on the surface of the silicon wafer, capable of absorbing some light. This is useful as a starting texture for additional RIE, because much shorter RIE times are possible on pre-textured (i.e. texture initiated) wafers. This is also useful when the solar cell is used in a tandem module as a bottom cell, because the mild texture is sufficient for light trapping, and no further texturing is required.

If a stronger texture is desired, then a metal catalyst (e.g., silver, copper, etc.) can be added directly to the etch bath (e.g., as metal compound, such as silver nitrate for example) to form metal catalyzed chemical etching (MCCE) texture, which follows the same embodiment etch process parameters as described above. In the embodiment where a metal catalyst is added to the mixture, a deep, cup-like texture can be made according to the catalytic oxidation described above. This oxidation results in a higher directionality (i.e., vertical etching) than the embodiment without a metal catalyst added. The cup-like texture may comprise recesses in the silicon surface, where each recess has a substantially vertical sidewall or sidewalls (e.g., sidewall(s) which are exactly perpendicular to the top silicon surface or which are within 20 degrees of perpendicular to the top silicon surface), and a curved, relatively convex bottom surface. The deep, cup-like texture that may be obtained in the embodiment which includes a metal catalyst is capable of absorbing more light than the shallow pitting that may be obtained with the mild texture in the embodiment without a metal catalyst.

The equations below further illustrate why less HF is needed in the higher temperature embodiment etching method relative to the conventional lower temperature (e.g., room temperature) etching method. Since HF is about ten times more expensive than nitric acid, a significant cost saving may be achieved by reducing the amount of HF used in the embodiment etching method.

The conventional etching summary equations which are conducted at lower temperatures are provided below. Specifically, silicon is oxidized to silicon dioxide by the nitric acid according to conventional equations a, b and c below:

Si+2HNO₃→SiO₂+2NO₂+H₂O a.

4HNO₃+Si→SiO₂+2H₂O+4NO₂ b.

4HNO₃+3Si→3SiO₂+H₂O+4NO. c.

The silicon dioxide is then dissolved by the hydrofluoric acid according to conventional equation d below:

SiO₂+6HF→H₂SiF₆+2H₂O. d.

As shown in equation d above, hexafluorosilicic acid (H₂SiF₆) is one of the reaction products of the conventional etching process. This acid builds up and cannot be removed from the etching bath in the etching vessel without removing unreacted etching chemicals using the bleed described above. Furthermore, etching 1 gram of silicon using the conventional etching method requires 7.4 mL of HF and 4.5 mL of HNO₃ to maintain steady state etching conditions. In practice, for conventional etching, when trying to maintain a bath in polishing regime, more makeup of HNO₃ is required to dilute the buildup of H₂O as a byproduct.

In contrast, the embodiment etching summary equations which are conducted at higher temperatures are provided below.

Si+2HNO₃→SiO₂+2NO₂+H₂O (I)

SiO₂+4HF→SiF₄+2H₂O (II)

As shown in equation II above, the embodiment etching method reaction products (i.e., byproducts) are SiF₄ and H₂O, which can both be removed as gases without a liquid bleed from the bath. However, in alternative embodiments, a liquid bleed may be used in the embodiment etching method. Furthermore, the embodiment etching method uses less than 7.4 mL of HF and less than 4.5 mL of HNO₃ to etch one gram of silicon while maintaining steady state etching conditions.

In one embodiment, stoichiometric ratios of HF and HNO₃, with respect to silicon etched, at elevated temperatures may be as follows: HF=3.8x (i.e., HF:Si=3.8:1), and HNO₃=1.8x (i.e., HNO₃:Si=1.8:1). Thus, 0.135 mol (e.g., 4.80 mL) of HF, and 0.064 mol (e.g., 3.93 mL) of HNO₃ may be used to etch 1 gram of silicon (i.e., 0.0356 mol silicon using 1 gram /28.0855 gram/mol=0.0356 mol silicon). This volume of 4.8 mL of HF and 3.93 mL of HNO₃ used to etch one gram of silicon in the embodiment method is much lower than 7.4 mL of HF and 4.5 mL of HNO₃ required to etch one gram of silicon and to maintain steady state etching conditions in the conventional method.

Furthermore, in the embodiment etching method, steady state etching conditions may be maintained with the addition of less than 2 mols HNO₃ per mol Si etched and 4 mols of HF used. This also reduces the cost of the nitric acid used to etch a predetermined amount of silicon. Specifically, the oxidation of silicon to silicon dioxide is not due to the reaction of silicon with nitric acid but rather due to a reaction of silicon with nitrogen dioxide (NO₂). NO₂ formation and silicon oxidation is as follows (where nitrous acid (HNO₂) is typically present in solution together with the nitric acid):

HNO₂+HNO₃→2NO₂+H₂O 1.

2NO₂+Si→Si²⁺+2NO₂₋ 2.

Si²⁺+2(OH)⁻→SiO2+H₂ 3.

NO₂ does not form readily at low temperatures. Therefore, a higher concentration of nitric acid is required in the conventional low temperature etching method. At high temperatures of the embodiment etching method, the nitric acid more rapidly converts to NO₂ (evidenced by color change to orange or brown) allowing the concentration of nitric acid in the bath to be much lower. This reduces nitric acid losses from drag out and bleed.

The embodiment methods may be used to reduce the cost of processing silicon wafers by as much as 10%. Using the embodiment methods also results in lower up-front cost due to the elimination of strong acid waste and the elimination of multiple steps used in the conventional etching method.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another.

1. A method comprising etching silicon using a mixture of nitric acid and hydrofluoric acid in which less than 6 mols of hydrofluoric acid is used to etch one mol of silicon at a temperature above room temperature.

2. The method of claim 1, wherein about 4 mols of hydrofluoric acid are used to etch one mol of silicon.

3. The method of claim 1, wherein the etching is conducted at a temperature of at least 70 degrees Celsius.

4. The method of claim 1, wherein the etching is conducted at a temperature of 70 to 130 degrees Celsius.

5. The method of claim 1, wherein the etching is conducted at a temperature of at least 90 degrees Celsius.

6. The method of claim 1, wherein the etching is conducted at a temperature of 90 to 110 degrees Celsius.

7. The method of claim 1, wherein the mixture further comprises a metal catalyst to form cup-like texture in surface of the silicon by metal catalyzed chemical etching.

8. The method of claim 1, wherein during the etching, the nitric acid oxidizes the silicon to silicon dioxide, and the hydrofluoric acid dissolves the silicon dioxide.

9. The method of claim 8, wherein:
the nitric acid oxidizes the silicon to the silicon dioxide by forming nitrogen dioxide which oxidizes the silicon according to equation (I):
Si+2HNO₃→SiO₂+2NO₂+H₂O (I); and
the hydrofluoric acid dissolves the silicon dioxide according to equation (II):
SiO₂+4HF→SiF₄+2H₂O (II).

10. The method of claim 8, wherein reaction products of the etching comprise silicon tetrafluoride gas and water vapor.

11. The method of claim 10, wherein the reaction products of the etching consist essentially of the silicon tetrafluoride gas and the water vapor, and include less than 1 mol percent of H₂SiF₆.

12. The method of claim 1, wherein 2 moles of less of the nitric acid are used to etch one mol of the silicon.

13. The method of claim 1, wherein the mixture further comprises a diluent comprising sulfuric acid.

14. The method of claim 13, wherein:
the diluent comprises at least 50 volume percent of the sulfuric acid and up to 50 volume percent water;
the etching is started when the mixture contacts the silicon in a vessel; and
there is no liquid bleed from the vessel during the etching.

15. The method of claim 1, wherein the silicon comprises polycrystalline silicon.

16. The method of claim 1, wherein the silicon comprises a polycrystalline silicon wafer.

17. The method of claim 16, further comprising forming a solar cell on the polycrystalline silicon wafer after the etching.

18. A method comprising etching silicon using a mixture of nitric acid and hydrofluoric acid at a temperature of at least 70 degrees Celsius.

19. The method of claim 1, wherein the etching is conducted at a temperature of 70 to 130 degrees Celsius, and the mixture further comprises a diluent comprising sulfuric acid.

20. A method comprising etching silicon using a mixture of nitric acid, hydrofluoric acid and sulfuric acid at above room temperature.
